(19) United States
(12) Patent Application Publication
(10) Pub. No.: US 2010/0136261 A1
(43) Pub. Date: Jun. 3, 2010

(54) MODULATION OF RF RETURNING STRAPS FOR UNIFORMITY CONTROL

(75) Inventors: Alan Tso, San Jose, CA (US); Daniel J. Hoffman, Saratoga, CA (US); Tsutomu (Tom) Tanaka, Santa Clara, CA (US); William N. Taylor, JR., Dublin, CA (US); Rongping Wang, Cupertino, CA (US); John M. White, Hayward, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/628,404

(22) Filed: Dec. 1, 2009

Related U.S. Application Data
(60) Provisional application No. 61/119,609, filed on Dec. 3, 2008.

(51) Int. Cl. C23C 16/00; H05H 1/24

(52) U.S. Cl. 427/569; 118/723 I

(57) ABSTRACT

Embodiments of the present invention generally relates to a method and apparatus for processing substrates using plasma. More particularly, embodiments of the present invention provide a plasma processing chamber having an electrode coupled to a plurality of RF returning straps, wherein impedance of the RF returning straps are set and/or adjusted to tune the plasma distribution during processing. In one embodiment, impedance of RF returning straps varies by changing length of the RF returning straps, by changing width of the RF returning straps, by changing spacing of the RF returning straps, by changing location of the RF returning straps, by adding a capacitor to the RF returning straps, or by combinations thereof.

### CROSS REFERENCE TO RELATED APPLICATIONS

This application claims priority to U.S. Provisional Patent Application Ser. No. 61/119,609 (attorney docket No. 13608L), filed Dec. 3, 2008, which is incorporated herein by reference.

### BACKGROUND OF THE INVENTION

1. Field of the Invention

Embodiments of the present invention generally relate to a method and apparatus for processing substrates, such as solar panel substrates, flat panel substrates, or semiconductor substrates, using plasma. More particularly, embodiments of the present invention relate to a radio frequency (RF) current return path for a plasma processing chamber.

2. Description of the Related Art

Plasma enhanced chemical vapor deposition (PECVD) is generally employed to deposit thin films on substrates, such as semiconductor substrates, solar panel substrates, and liquid crystal display (LCD) substrates. Plasma enhanced chemical vapor deposition is generally accomplished by introducing a precursor gas into a vacuum chamber having a substrate disposed on a substrate support. The precursor gas is typically directed through a distribution plate situated near the top of the vacuum chamber. The precursor gas in the vacuum chamber is energized (e.g., excited) into a plasma by applying an RF power to the chamber from one or more RF sources coupled to the chamber. The excited gas reacts to form a layer of material on a surface of a substrate that is positioned on a temperature controlled substrate support. The distribution plate is generally connected to a RF power source and the substrate support is typically connected to the chamber body providing a RF current returning path.

Uniformity is generally desired in the thin films deposited using PECVD process. For example, an amorphous silicon film, such as microcrystalline silicon film or microcrystalline silicon film, or a polycrystalline silicon film is usually deposited using PECVD on a flat panel for forming p-n junctions required in transistors or solar cells. The quality and uniformity of the amorphous silicon film or polycrystalline silicon film are important for commercial operation. Therefore, there is a need for PECVD chambers with improved uniformity.

### SUMMARY OF THE INVENTION

Embodiments of the present invention generally relate to a method and apparatus for plasma processing a substrate. More particularly, embodiments of the present invention provide a plasma processing chamber having RF returning straps straps configured to improve uniformity.

One embodiment of the present invention provides a method for processing a substrate using plasma comprising providing a process chamber defining a processing volume, wherein a substrate support is disposed in the processing volume, a gas distribution plate connected with a radio frequency (RF) power source is disposed over the substrate support, and a periphery of the substrate support is connected with the RF power source via a plurality of RF returning straps, flowing one or more processing gases to the processing volume through the distribution plate, and applying a radio frequency power to the gas distribution plate to generate a plasma from the one or more processing gases in the processing volume, wherein impedance of one or more RF returning straps has been modified to adjust local plasma distribution between the gas distribution plate and the substrate.

Another embodiment of the present invention provides an apparatus for processing a substrate comprising a chamber body defining a processing volume, wherein the chamber body has a slit valve opening configured to allow passages of substrates, a substrate support disposed in the processing volume, wherein the substrate support is configured to receive a substrate on a supporting surface and to support the substrate during processing, a gas distribution plate disposed in the processing volume and above the substrate support, wherein the gas distribution plate is configured to deliver one or more processing gas, a radio frequency power source connected with the gas distribution plate, and a plurality of RF returning straps connected between a periphery of the substrate support and the RF power source, wherein the plurality of RF returning straps is disposed such that impedance between the substrate support and the RF power source varies along the periphery of the substrate support.

Yet another embodiment of the present invention provides an apparatus for processing a substrate comprising a chamber body defining a processing volume, a first electrode disposed in the processing volume, a second electrode disposed in the processing volume, wherein the second electrode is opposing the first electrode and the first and second electrodes form a plasma volume therebetween, a radio frequency power source coupled to the first electrode, and a plurality of RF returning straps coupled between the second electrode and a body at a predetermined electrical potential, wherein the plurality of RF returning straps are coupled to a periphery of the second electrode, and impedance of the plurality of RF returning straps varies along the periphery of the second electrode.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A schematically illustrates RF returning straps for a plasma processing system for PECVD in accordance with one embodiment of the present invention.

FIG. 1B is a schematic top view of the plasma processing system of FIG. 1A.

FIG. 2A schematically illustrates a sectional side view of a plasma processing chamber in accordance with one embodiment of the present invention.

FIG. 2B schematically illustrates an RF returning strap connection in accordance with one embodiment of the present invention.

FIG. 2C schematically illustrates an RF returning strap in accordance with one embodiment of the present invention.

FIGS. 3-7 schematically illustrate RF returning strap arrangements in accordance with embodiments of the present invention.

FIG. 8 schematically illustrates a RF returning strap arrangement to compensate for chamber asymmetry in accordance with one embodiment of the present invention.

FIG. 9 is a cross sectional view of an exemplary silicon-based thin film photovoltaic (PV) solar cell.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the present invention generally relates to a method and apparatus for processing substrates using plasma. More particularly, embodiments of the present invention provide a plasma processing chamber having an electrode coupled to a plurality of RF returning straps, wherein impedance of the RF returning straps are set and/or adjusted to tune the plasma distribution during processing. In one embodiment, impedance of RF returning straps varies by changing length of the RF returning straps, by changing width of the RF returning straps, by changing spacing of the RF returning straps, by changing location of the RF returning straps, by adding a variable capacitor to the RF returning straps, or by combinations thereof.

Embodiments of the present invention are generally utilized in processing rectangular substrates, such as substrates for liquid crystal displays or flat panels, and substrates for solar panels. Other suitable substrates may be circular, such as semiconductor substrates. The present invention may be utilized for processing substrates of any size or shape. However, the present invention provides particular advantage in sizes 15K (about 15,600 cm²), 25K (about 27,750 cm²), and above, more preferably 40K (about 41,140 cm²) and above, for example 50K, 55K, and 60K, due to the increased RF returning required for larger susceptors.

Although the invention is illustratively described, shown and practiced within a large area substrate processing system, the invention may find utility in other plasma processing systems, including those from other manufacturers where it is desirable to ensure that one or more RF returning paths remain functioning at a level that facilitates acceptable processing within the system. Other exemplary processing systems on which the invention may be practiced include the CENTURA ULTIMA HDP-CVD™ system, the PRODUCER APF PECVD™ system, the PRODUCER BLACK DIAMOND™ system, the PRODUCER BLOK PECVD™ system, the PRODUCER DARC PECVD™ system, the PRODUCER HARP™ system, the PRODUCER PECVD™ system, the PRODUCER STRESS NITRIDE PECVD™ system, and the PRODUCER TEOS FSG PECVD™ system, all of which are available from Applied Materials, Inc. of Santa Clara, Calif.

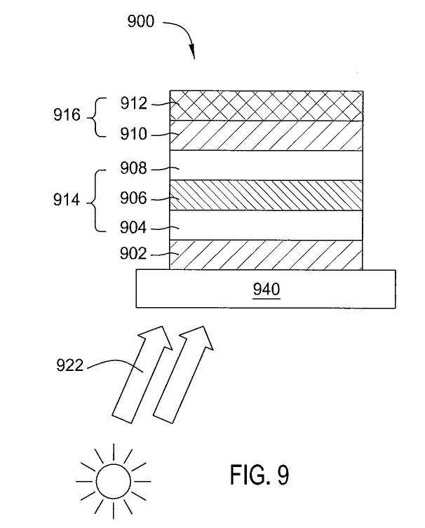

Embodiments of the present invention may be used to form numerous different types of films that can be used to form a thin-film solar cell, such as an exemplary cross sectional view of a silicon-based thin film photovoltaic (PV) solar cell 900 shown in FIG. 9. The silicon-based thin film PV solar cell 900 may generally comprise a transparent conducting oxide (TCO) layer 902 formed on a substrate 940, a photoelectric conversion unit 914 formed on the transparent conducting oxide layer 902, and a backside electrode 916 formed on the photoelectric conversion unit 914. The backside electrode 916 may be formed by a stacked film that includes a transparent conducting oxide (TCO) layer 910 and a conductive layer 912.

In operation, incident light 922 provided by the environment, e.g, sunlight or other photons, is supplied to the PV solar cell 900. The photoelectric conversion unit 914 in the PV solar cell 900 absorbs the light energy and converts the light energy into electrical energy within p-i-n junction(s) formed in the photoelectric conversion unit 914, thereby generating electricity or energy. Alternatively, the PV solar cell 900 may be fabricated or deposited in a reversed order, or may comprise two or more photoelectric conversion units stacked together and separated by transparent conducting oxide layers.

The substrate 940 may be thin sheet of metal, plastic, organic material, silicon, glass, quartz, or polymer, among others suitable materials. The substrate 940 may have a surface area greater than about 1 square meters, such as greater than about 2 square meters. An optional dielectric layer (not shown) may be disposed between the substrate 940 and a transparent conducting oxide (TCO) layer 902. In one embodiment, the optional dielectric layer may be a SiON or silicon oxide (SiO₂) layer.

The transparent conducting oxide (TCO) layers 902, 910 may include, but not limited to, at least one oxide layer selected from a group consisting of tin oxide (SnO₂), indium tin oxide (ITO), zinc oxide (ZnO), or the combination thereof. The TCO layer 902 may be deposited by a CVD process, a PVD process, or other suitable deposition process.

The conductive layer 912 may include, but not limited to, a metal layer selected from a group consisting of Ti, Cr, Al, Ag, Au, Cu, Pt, or an alloy of the combination thereof.

The photoelectric conversion unit 914 comprises a p-type semiconductor layer 904, an n-type semiconductor layer 908, and an intrinsic type (i-type) semiconductor layer 906. The i-type semiconductor layer 906 is also known as the bulk layer functioning as a photoelectric conversion layer generating electron-hole pairs from incident light energy. An intrinsic semiconductor is distinguished from an extrinsic semiconductor by the addition of dopant atoms in the extrinsic semiconductor. The extrinsic semiconductor layers, such as the p-type semiconductor layer 904 and the n-type semiconductor layer 908, are used to collecting electrons or holes generated by the intrinsic semiconductor in solar cells.

An intrinsic semiconductor layer may be formed by providing a gas mixture comprising a source of the semiconductor material to be formed. For example, intrinsic silicon layer may be formed by providing a gas mixture comprising silane and hydrogen gas to a processing chamber. Silicon and other semiconductors formed from the gas mixture may have varying degrees of crystallinity depending on processing parameters.

Materials in which atoms have essentially no arranged definite pattern, or crystallinity, are referred to as being amorphous. A completely crystalline material is referred to as crystalline, polycrystalline, or monocrystalline material. A polycrystalline material is crystalline material formed into numerous crystal grains separated by grain boundaries. Monocrystalline materials are single crystal materials.

Semiconductor solids having partial crystallinity, that is a crystal fraction between about 5% and about 95%, are referred to as nanocrystalline or microcrystalline, generally referring to the size of crystal grains suspended in an amorphous phase.

Nanocrystalline silicon, frequently called microcrystalline silicon, is paracrystalline having short- or medium-range ordering, and consists of a mixture of two phases—small crystalline grains embedded in an amorphous matrix. Nanocrystalline and microcrystalline are sometimes distinguished by the size of the crystal grains (or crystallites). However, most paracrystalline silicon with grains extending into the micrometer range is actually fine-grained polysilicon having no amorphous matrix between the crystals, so the term “nanocrystalline” is considered by some to be a better choice of terminology than “microcrystalline” when referring to two-phase paracrystalline silicon.

Another approach from the late 1990s was to similarly define microcrystalline silicon as having two phases, i.e. crystal grains in an amorphous matrix, but limited to crystal grains of <20 nm feature size. In contrast, polysilicon was defined as being a single-phase crystalline material with no amorphous matrix between the crystals in which the smallest crystal dimension was >20 nm.

It should be noted that the term “crystalline silicon/semiconductor” may refer to any form of silicon/semiconductor having a crystal phase, including microcrystalline and nanocrystalline silicon/semiconductor.

Crystallinity of an intrinsic semiconductor layer influences light-absorbing characteristics of the intrinsic semiconductor layer. For example, an amorphous semiconductor layer will generally absorb light at different wavelengths from intrinsic layers having different degrees of crystallinity, such as microcrystalline silicon. For this reason, most solar cells will use both amorphous and microcrystalline/nanocrystalline layers to yield the broadest possible light absorption characteristics. An intrinsic semiconductor layer can be formed by depositing multiple microcrystalline semiconductor layers to achieve a desired nominal crystal fraction, a film having a graded crystalline fraction, or a varying crystalline fraction throughout the layer.

The p-type and n-type semiconductor layers 904, 908 may be silicon based materials doped by an element selected either from group III or V. A silicon film doped with a group III element (e.g., boron (B)) is referred to as a p-type silicon film, while a silicon film doped with a group V element (e.g., phosphorous (P)) is referred to as a n-type silicon film. In one embodiment, the n-type semiconductor layer 908 may be a phosphorus doped silicon film and the p-type semiconductor layer 904 may be a boron doped silicon film.

The doped silicon film may be an amorphous silicon film (a-Si), a polycrystalline film (poly-Si), or a microcrystalline film (μc-Si) with a thickness generally between about 5 nm and about 50 nm. Alternatively, the doped element in semiconductor layer 904, 908 may be selected to meet device requirements of the PV solar cell 900. The n-type and p-type semiconductor layers 908, 904 may be deposited using processing chambers in accordance with embodiments of the present invention.

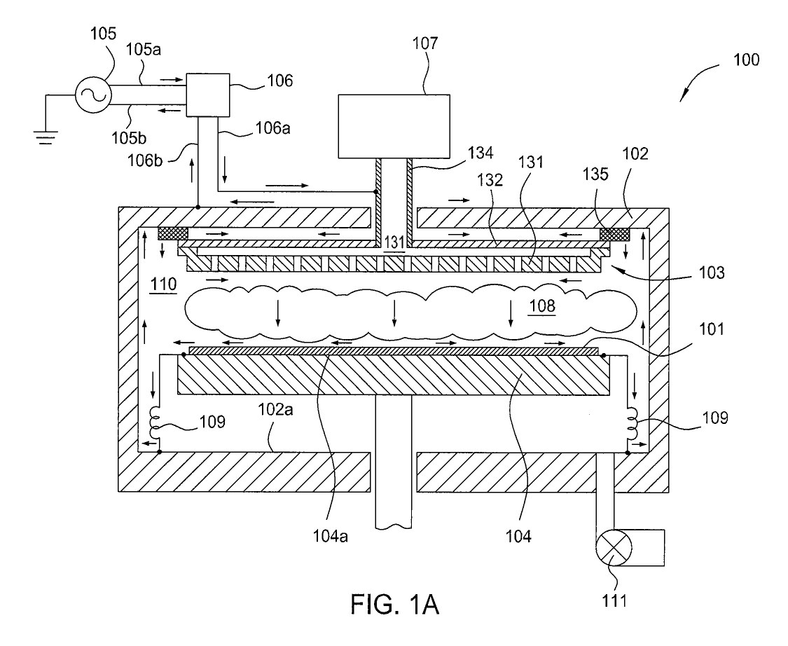

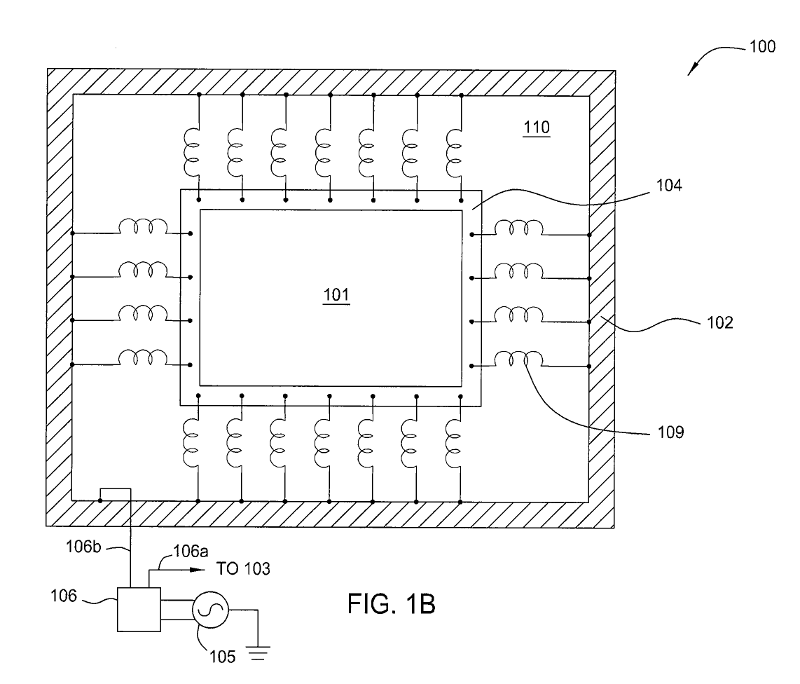

FIG. 1A schematically illustrates RF returning straps for a plasma processing system 100 for PECVD in accordance with one embodiment of the present invention. The plasma processing system 100 is configured to process a large area substrate 101 using plasma in forming structures and devices on the large area substrate 101 for use in the fabrication of liquid crystal displays (LCD's), flat panel displays, organic light emitting diodes (OLED's), or photovoltaic cells for solar cell arrays. The structures may be a plurality of back channel etch inverted staggered (bottom gate) thin film transistors which may comprise a plurality of sequential deposition and masking steps. Other structures may include p-n junctions to form diodes for photovoltaic cells.

The plasma processing system 100 may be configured to deposit a variety of materials on the large area substrates 101, including but not limited to dielectric materials (e.g., SiO₂, SiOₓN_{y}, derivatives thereof or combinations thereof), semiconductive materials (e.g., Si and dopants thereof), barrier materials (e.g., SiNₓ, SiOₓN_{y} or derivatives thereof). Specific examples of dielectric materials and semiconductive materials that are formed or deposited by the plasma processing system 100 onto the large area substrates may include epitaxial silicon, polycrystalline silicon, amorphous silicon, microcrystalline silicon, silicon germanium, germanium, silicon dioxide, silicon oxynitride, silicon nitride, dopants thereof (e.g., B, P, or As), derivatives thereof or combinations thereof. The plasma processing system 100 is also configured to receive gases such as argon, hydrogen, nitrogen, helium, or combinations thereof, for use as a purge gas or a carrier gas (e.g., Ar, H₂, N₂, He, derivatives thereof, or combinations thereof). One example of depositing silicon thin films on the large area substrate 101 using the system 100 may be accomplished by using silane as the precursor gas in a hydrogen carrier gas.

Examples of various devices and methods of depositing thin films on a large area substrate using the system 100 may be found in U.S. patent application Ser. No. 11/021,416, filed Nov. 17, 2005, published as U.S. 2005-0255257, entitled “Method Of Controlling The Film Properties Of PECVD-Deposited Thin Films,” and U.S. patent application Ser. No. 11/173,210, filed Jul. 1, 2005, published as U.S. 2006-0228496, entitled “Plasma Uniformity Control By Gas Diffuser Curvature,” which are both incorporated by reference herein to the extent the applications are not inconsistent with this specification. Other examples of various devices that may be formed using the system 100 may be found in U.S. patent application Ser. No. 10/889,683, filed Jul. 12, 2004, published as U.S. 2005-0251990, entitled “Plasma Uniformity Control by Gas Diffuser Hole Design,” and in U.S. Pat. No. 7,125,758, issued Oct. 24, 2006, entitled “Controlling the Properties and Uniformity of a Silicon Nitride Film by Controlling the Film Forming Precursors,” both of which are incorporated by reference herein to the extent not inconsistent with this specification.

As shown in FIG. 1, the plasma processing system 100 generally comprises a chamber body 102 defining a processing volume 110. A substrate support 104 is disposed in the processing volume 110. The substrate support 104 is configured to support the substrate 101 on a top surface 104a during processing. The substrate support 104 is also configured to move vertically during processing to adjust a distance between the substrate 101 and a showerhead assembly 103 configured to supply a processing gas to the processing volume 110 from a processing gas source 107. The plasma processing system 100 also comprises an exhaust system 111 configured to vacuum the processing volume 110. The showerhead assembly 103 is generally disposed opposing the substrate support 104 in a parallel manner.

In one embodiment, the showerhead assembly 103 comprises a gas distribution plate 131 and a blocker plate 132. A gas volume 133 is formed between the gas distribution plate 131 and the blocker plate 132. The gas source 107 is connected to the gas volume 133 via a gas supplying conduit 134.

The gas distribution plate 131, the blocker plate 132, and the gas supplying conduit 134 are generally formed from electrically conductive materials and are in electrical communication with one another. The chamber body 102 is also formed from an electrically conductive material. The chamber body 102 is generally electrically insulated from the showerhead assembly 103. In one embodiment, the showerhead assembly 103 is mounted on the chamber body 102 via an insulator 135.

In one embodiment, the substrate support 104 is also electrically conductive, and the substrate support 104 and the showerhead assembly 103 are configured to be opposing electrodes for generating plasma therebetween.

An RF power source 105 is generally used to generate a plasma between the showerhead assembly 103 and the substrate support 104. In one embodiment, the RF power source 105 is coupled to the showerhead 103 via a first output 106a of an impedance matching circuit 106. A second output 106b of the impedance matching circuit 106 is electrically connected to the chamber body 102.

In one embodiment, a plurality of RF returning straps 109 are electrically connected between the substrate support 104 and the chamber body 102. The plurality of RF returning straps 109 are configured to shorten the path for RF current during processing, and to adjust plasma uniformity near an edge area of the substrate support 104.

The path of the RF current is schematically illustrated by arrows in FIG. 1A. The RF current generally travels from a first output 105a of the RF power source 105 to the first output 106a of the impedance match circuit 106, then travels along an outer surface of the gas supplying conduit 134 to a back surface of the blocker plate 132, then to a front surface of the gas distribution plate 131. From the front surface of the gas distribution plate 131, the RF current goes through plasma 108 and reaches a top surface of the substrate 101 or the substrate support 104, then through the plurality of RF returning straps 109 to an inner surface 102a of the chamber body 102. From the inner surface 102a, the RF current returns to a second output 105b of the RF power source 105 via the second output 106b of the impedance matching circuit 106.

FIG. 1B is a schematic top view of the plasma processing system 100. FIG. 1B schematically illustrates an arrangement of the plurality of RF returning straps 109 in relation to the substrate support 104. The plurality of RF returning straps 109 are distributed along edges of the substrate support 104. Each RF returning strap 109 may comprises a wide flexure having one end electrically connected to a surface of the substrate support 104 and another end electrically connected to the chamber body 102. The plurality of RF returning straps 109 allow the relative motion between the substrate support 104 and the chamber body 102. Each RF returning strap 109 may have different electrical properties adjusted to the location of the RF returning strap 109. In one embodiment, the impedance of the RF returning straps 109 is adjusted to tune local plasma distribution.

Referring back FIG. 1A, during processing, one or more processing gas is flown to the processing volume 110 from the gas source 107 through the showerhead 103. A RF power is applied between the showerhead 103 and the substrate support 104 generating a plasma 108 for processing the substrate 101. Uniformity of plasma distribution is generally desired during processing. However, the distribution of the plasma 108 is determined by variety of factors, such as distribution of the processing gas, geometry of the processing volume 110, the distance between the electrodes, and electrical properties of the RF returning straps 109.

In one embodiment of the present invention, plasma distribution within the processing volume 110 may be adjusted by adjusting one or more property of the one or more of the plurality of RF returning straps 109. In one embodiment, the property of the RF returning straps 109 may be adjusted by adjusting location of the RF returning straps 109, adjusting width of the RF returning straps 100, adjusting length of the RF returning straps 109, adjusting spacing between neighboring RF returning straps 109, adding a variable or fixed capacitor, or combinations thereof.

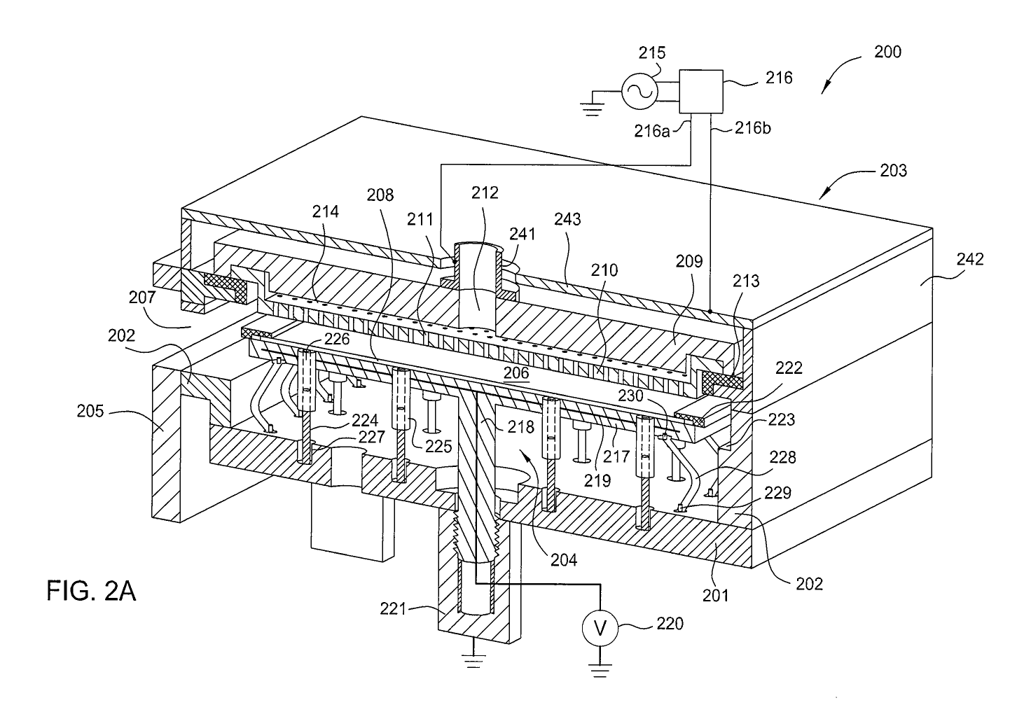

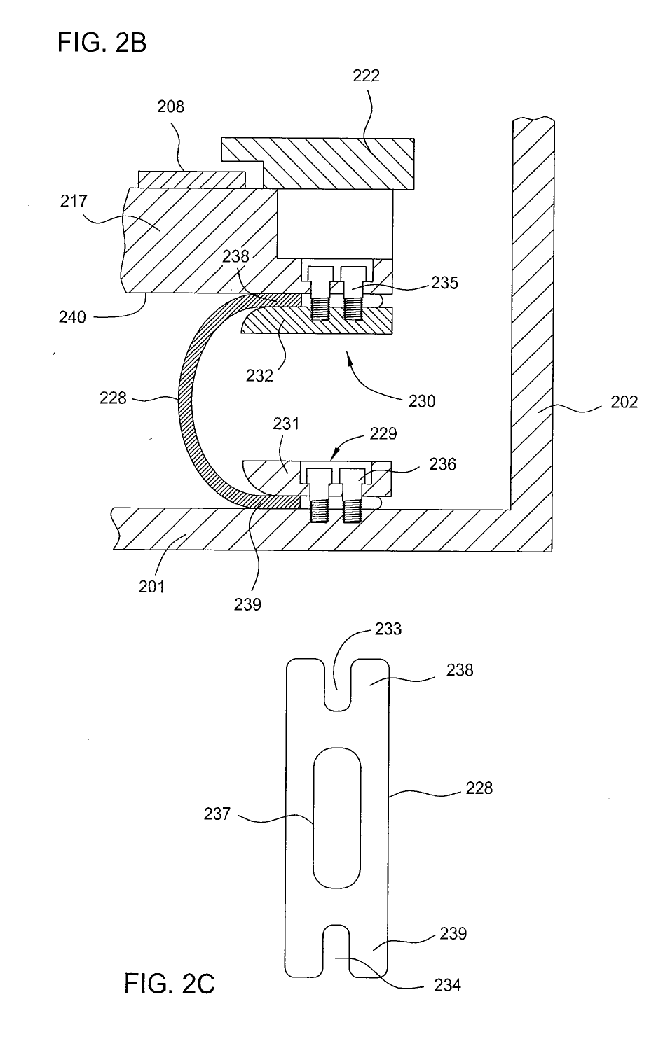

FIG. 2 schematically illustrates a sectional side view of a plasma processing chamber 200 in accordance with one embodiment of the present invention.

The plasma processing chamber 200 comprises a chamber bottom 201, sidewalls 202, and a lid assembly 203. The chamber bottom 201, sidewalls 202, and the lid assembly 203 define a processing volume 206. A substrate support assembly 204 is disposed in the processing volume 206. An opening 207 is formed through one side of the sidewalls 202. The opening 207 is configured to allow passages of substrate 208. A slit valve 205 is coupled to the sidewall 202 and configured to close the opening 207 during processing.

The lid assembly 203 is supported by the sidewalls 202 and can be removed to service the interior of the plasma processing chamber 200. The lid assembly 203 comprises an outer lid 242, a lid cover plate 243, a blocker plate 209, a distribution plate 210, a gas conduit 241, and an isolator 213.

The blocker plate 209 and the distribution plate 210 are disposed substantially parallel to each other forming a gas distribution volume 214 therebetween. The blocker plate 209 and distribution plate 210 are configured to distribute a processing gas to the processing volume 206. The blocker plate 209 and the distribution plate 210 are typically fabricated from aluminum. The isolator 213 is disposed on the sidewalls 202 and configured to electrically isolate the sidewalls 202 from the distribution plate 210 and the blocker plate 209. The lid cover plate 243 is supported by the outer lid 242, and electrically connected to the sidewalls 202.

An opening 212 is formed through the blocker plate 209 and is configured to connect the gas distribution volume 214 via the gas conduit 241 to a gas source (not shown). The distribution plate 210 has a perforated area near a center section. A plurality of holes 211 are formed through the distribution plate 210 and provide fluid communication between the gas distribution volume 214 and the processing volume 206. The perforated area of the distribution plate 210 is configured to provide a uniform distribution of gases passing through the distribution plate 210 into the processing volume 206.

The substrate support assembly 204 is centrally disposed within the processing volume 206 and supports the substrate 208 during processing. The substrate support assembly 204 generally comprises an electrically conductive support body 217 supported by a shaft 218 which extends through the chamber bottom 201. The support body 217 is generally polygonal in shape and covered with an electrically insulative coating over at least the portion of the support body 217 that supports the substrate 208. The insulative coating may also cover other portions of the support body 217. In one embodiment, the substrate support assembly 204 is normally coupled to a ground potential at least during processing.

The support body 217 may be fabricated from metals or other comparably electrically conductive materials, for example, aluminum. The insulative coating may be a dielectric material such as an oxide, silicon nitride, silicon dioxide, aluminum dioxide, tantalum pentoxide, silicon carbide or polyimide, among others, which may be applied by various deposition or coating processes, including, but not limited to, flame spraying, plasma spraying, high energy coating, chemical vapor deposition, spraying, adhesive film, sputtering and encapsulating.

In one embodiment, the support body 217 encapsulates at least one embedded heating element 219 configured to heat the substrate 208 during processing. In one embodiment, the support body 217 also comprises a thermocouple for temperature control. In one embodiment, the support body 217 may comprise one or more stiffening members comprised of metal, ceramic or other stiffening materials embedded therein.

The heating element 219, such as an electrode or resistive element, is coupled to a power source 220 and controllably heats the support assembly 204 and substrate 208 positioned thereon to a predetermined temperature. Typically, the heating element 219 maintains the substrate 208 at a uniform temperature of about 150 to at least about 460 degrees Celsius during processing. The heating element 219 is electrically floating relative to the support body 217.

The shaft 218 extends from the support body 217 through the chamber bottom 201 and couples the substrate support assembly 204 to a lift system 221. The lift system 221 moves the substrate support assembly 204 between an elevated processing position (as shown in FIG. 2) and a lowered position that facilitates substrate transfer.

In one embodiment, the substrate support assembly 204 comprises a circumscribing shadow frame 222. The circumscribing shadow frame 222 is configured to prevent deposition or other processing on edges of the substrate 208 and the support body 217 during processing. The circumscribing shadow frame 222 rests on the substrate 208 and the support body 217 when the substrate support assembly 204 is in an elevated processing position, as shown in FIG. 2. When the substrate support assembly 204 is in a lowered position for substrate transferring, the circumscribing shadow frame 222 rests above the substrate support assembly 204 on a step 223 formed on the sidewalls 202.

In one embodiment, the support body 217 has a plurality of pin holders 225 disposed therethrough configured to direct a plurality of lifting pins 224. Each pin holder 225 has a through hole 226 formed therein. The through hole 226 opens to an upper surface of the support body 217. Each pin holder 225 is configured to receive one lifting pin 224 from a lower opening of the through hole 226. Each lifting pin 224 extends upward from a recess 227 formed in the chamber bottom 201. As the support body 217 lowers along with the plurality of pin holders 225, the plurality of lifting pins 224 poke through the through holes 226 picking up the substrate 208. The substrate 208 is then separated from the support body 217 allowing a substrate handler to transfer the substrate 208 out of the plasma processing chamber 200.

The plurality of lifting pins 224 are typically comprised of ceramic or anodized aluminum. In one embodiment, the plurality of lifting pins 224 may have various lengths so that they come into contact with the substrate 208 at different times. For example, the lifting pins 224 that are spaced around the outer edges of the substrate 208 are taller than the lifting pins 224 spaced inwardly from the outer edges toward the center of the substrate 224, allowing the substrate 208 to be first lifted from its outer edges relative to its center.

An RF power source 215 is used to generate plasma in the processing volume 206. In one embodiment, an impedance matching circuit 216 is coupled to the RF power source 215. A first output 216a of the impedance matching circuit 216 is connected with the gas distribution plate 210, and a second output 216b of the impedance matching circuit 216 is connected with the substrate support assembly 204, thus, applying a RF power between the processing gas disposed between the gas distribution plate 210 and the substrate support assembly 204 and generating and sustaining a plasma for processing the substrate 208 on the substrate support assembly 204.

In one embodiment, the first output 216a of the impedance matching circuit 216 is connected with the distribution plate 210 via the gas conduit 241 and the blocker plate 209. In one embodiment, the second output 216b is coupled to the chamber body, e.g. the sidewalls 202, or the lid cover plate 243.

In one embodiment, a plurality of RF returning straps 228 are connected between the support body 217 of the substrate support assembly 204 to the chamber bottom 201 which is connected to the second output 216b of the impedance matching circuit 216. The plurality of RF returning straps 228 provide an RF current return path between the support body 217 and the chamber bottom 201.

In one embodiment, the plurality of RF returning straps 228 are unevenly distributed along each edge of the support body 217 with varying spacing between neighboring RF returning straps 228. In one embodiment, the plurality of RF returning straps 228 are distributed asymmetrically reflecting asymmetric feature of the chamber geometry, and/or asymmetric features of gas flow distribution. In one embodiment, no RF returning straps 228 are disposed near corners of the support body 217.

In another embodiment, each of the plurality RF returning straps 228 has different electrical property depending on location of each RF returning strap 228. In one embodiment, at least one of the plurality of RF returning straps 228 has adjustable electrical properties. In one embodiment, the adjustable electrical property is impedance of the RF returning strap 228.

FIG. 2C schematically illustrates one embodiment of the RF returning strap 228. The RF returning strap 228 is generally a flat soft conductive band which is flexible and does not exert a significant restoring force when bent. In one embodiment, the RF returning strap 228 comprises a flexible, low impedance conductive material which is resistant to processing and cleaning chemistries. In one embodiment, the RF returning strap 228 is comprised of aluminum. Alternatively, the RF returning strap 228 may comprise titanium, stainless steel, beryllium copper or a flexible material that is coated with a conductive metallic coating.

In one embodiment, the RF returning strap 228 has a first end 238 and a second end 239. The first end 238 has a mounting slot 233 and the second end 233 has a mounting slot 234. In one embodiment, the RF returning strap 228 has a central slot 237 configured to increase the flexibility of the RF returning strap 228.

FIG. 2B schematically illustrates RF returning strap connections used in the plasma processing chamber 200. The first end 238 of the RF returning strap 228 is electrically coupled to the support body 217 via a connection assembly 230. In one embodiment, the connection assembly 230 is connected to a lower side 240 of the support body 217. The second end 239 is electrically coupled to the chamber bottom 201 by a connection assembly 229. The RF returning strap 228 may be coupled to the support body 217 and the chamber bottom 201 via other means such as, for example, fasteners, clamps or other methods that maintain electrical connection between the support body 217, the RF returning strap 228, and the chamber bottom 201. As shown in FIG. 2B, the connection assembly 230 comprises a shaped clamp 232 and one or more screws 235. The connection assembly 229 comprises a shaped clamp 231 and one or more screws 236.

The connection assemblies 229, 230 each comprise low impedance conductive materials that are resistant to processing and cleaning chemistries. In one embodiment, the connection assemblies 229, 230 comprise aluminum. Alternatively, the materials may comprise titanium, stainless steel, beryllium copper or any material that is coated with a conductive metallic coating. In another embodiment, the connection assembly 229 comprises a first conductive material and the connection assembly 230 comprises a second conductive material, wherein the first conductive material and the second conductive material are different materials.

Embodiments of different RF returning straps may be found in U.S. patent application Ser. No. 11/775.359 (Attorney Docket No. 12004), filed Jul. 10, 2007, entitled “Asymmetric Grounding of Rectangular Susceptor”, published as United States Patent Application Publication 2008/0274297, which are incorporated herein by reference.

In one embodiment, electrical properties of the RF returning straps 228 are adjusted to tune local plasma distribution. In one embodiment, electrical properties of the RF returning straps 228 can be adjusted to improve uniformity of the plasma formed between the distribution plate 210 and the support body 204.

In one embodiment, impedance of each RF returning straps 228 can be changed to adjust local plasma distribution. In one embodiment, local plasma distribution near a RF returning strap 228 may be increased by reducing impedance of the RF returning strap 228, and local plasma distribution near the RF returning strap 228 may be decreased by increasing the impedance of the RF returning strap 228.

In another embodiment, plasma distribution in the plasma processing chamber 200 can be adjusted by adjusting location, and/or spacing of the plurality of RF returning straps 228.

The electrical properties of each RF returning strap 228 may be adjusted by varying length of the RF returning strap 228, varying width of the RF returning strap 228, serially or parallelly connecting a variable capacitor to the RF returning strap 228, adjusting spacing of the neighboring RF returning straps, or combinations thereof.

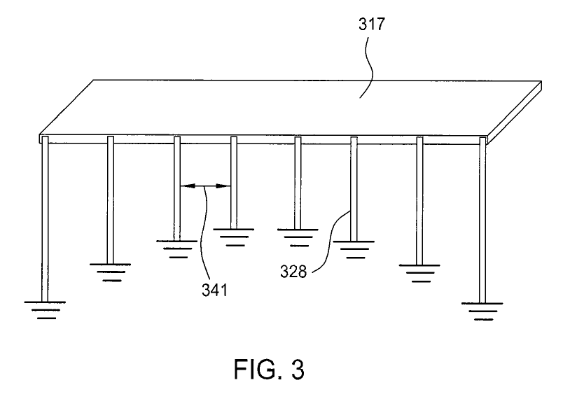

FIGS. 3-7 schematically illustrate RF returning strap arrangements to improve plasma uniformity in accordance with embodiments of the present invention.

FIG. 3 schematically illustrates one arrangement of RF returning straps 328 along one side of a rectangle substrate support body 317, similar to the support body 217 of FIG. 2A. A plurality of RF returning straps 328 are evenly distributed along a side of the support body 317. This arrangement increases plasma uniformity along the side of the substrate support body 317. Spacing 341 between neighboring RF returning straps is substantially the same, width of each RF returning straps 328 is substantially the same, and length of each RF returning strap 328 varies along the side. In one embodiment, the length of RF returning straps 328 is longer near the ends of the side and gradually decreases towards the center of the side. Although only one side of the substrate support body 317 is shown, remaining sides of the substrate support body 317 are also connected to a plurality of RF returning straps. Similar RF returning strap arrangement or different RF returning strap arrangement can be applied to the remaining sides not shown.

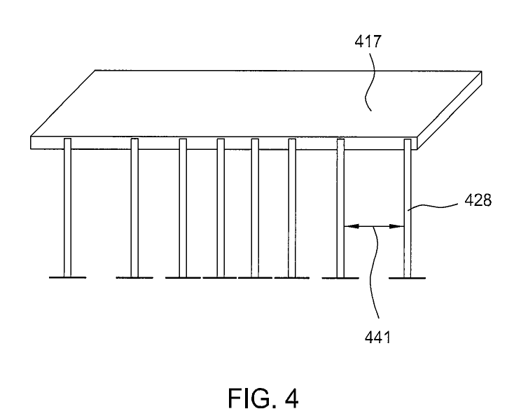

FIG. 4 schematically illustrates one arrangement of RF returning straps 428 along one side of a rectangle substrate support body 417, similar to the support body 217 of FIG. 2A. A plurality of RF returning straps 428 are distributed along a side of the support body 417. This arrangement increases plasma uniformity along the side of the substrate support body 417. Width of each RF returning straps 428 is substantially the same, length of each RF returning strap 428 is also substantially the same, while spacing 441 between neighboring RF returning straps 428 varies along the side. In one embodiment, the spacing 441 of neighboring RF returning straps 328 is bigger near the ends of the side and gradually decreases towards the center of the side. Although only one side of the substrate support body 417 is shown, remaining sides of the substrate support body 417 are also connected to a plurality of RF returning straps. Similar RF returning strap arrangement or different RF returning strap arrangement can be applied to the remaining sides not shown.

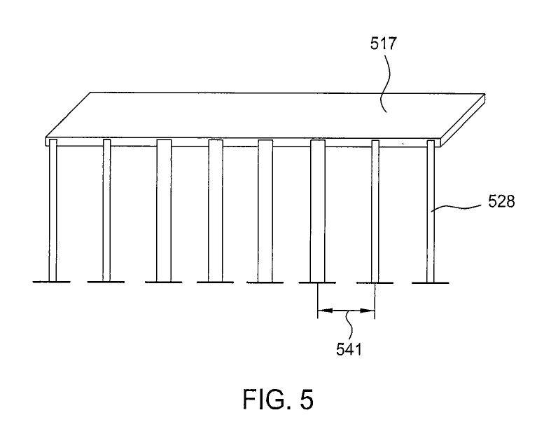

FIG. 5 schematically illustrates one arrangement of RF returning straps 528 along one side of a rectangle substrate support body 517, similar to the support body 217 of FIG. 2A. A plurality of RF returning straps 528 are distributed along a side of the support body 517. This arrangement increases plasma uniformity along the side of the substrate support body 517. Length of each RF returning strap 528 is also substantially the same, spacing 541 between neighboring RF returning straps 528 is substantially the same, while width of each RF returning straps 528 varies along the side. In one embodiment, the width of RF returning straps 528 is smaller near the ends of the side and increases towards the center of the side. Although only one side of the substrate support body 517 is shown, remaining sides of the substrate support body 517 are also connected to a plurality of RF returning straps. Similar RF returning strap arrangement or different RF returning strap arrangement can be applied to the remaining sides not shown.

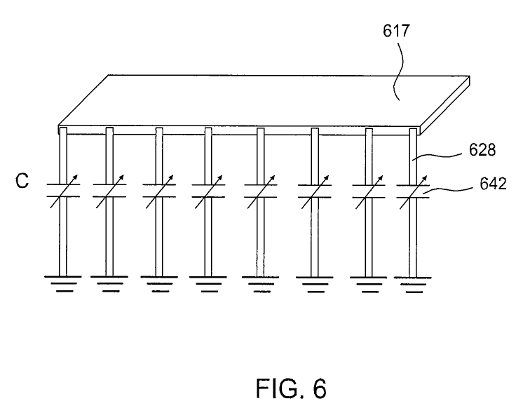

FIG. 6 schematically illustrates one arrangement of RF returning straps 628 along one side of a rectangle substrate support body 617, similar to the support body 217 of FIG. 2A. A plurality of RF returning straps 628 are evenly distributed along a side of the support body 617. Each RF returning strap 628 comprises a variable capacitor 642 serially connected therein. The length, width, and spacing of the RF returning straps 628 are substantially the same. The variable capacitor 642 of each RF returning strap 628 can be individually adjusted. Therefore, impedance of each RF returning strap 628 can be adjusted according to location of the RF returning strap 628 to improve uniformity along the side. Although only one side of the substrate support body 617 is shown, remaining sides of the substrate support body 617 are also connected to a plurality of RF returning straps. Similar RF returning strap arrangement or different RF returning strap arrangement can be applied to the remaining sides not shown.

The arrangements of FIGS. 3-6 can be used alone or in combination. In one embodiment, the same arrangement may be used in all sides of a substrate support. In another embodiment, different arrangement may be used in each side of the substrate support. In another embodiment, the different arrangement may be used in combination along one side of a substrate support.

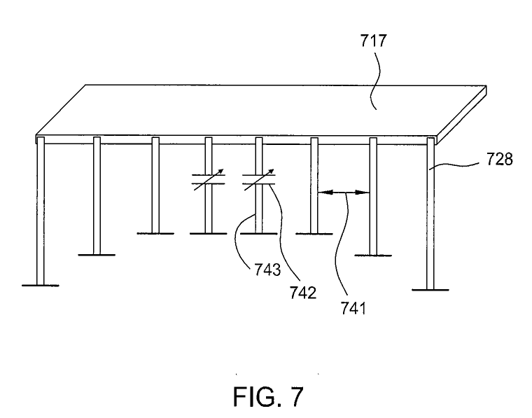

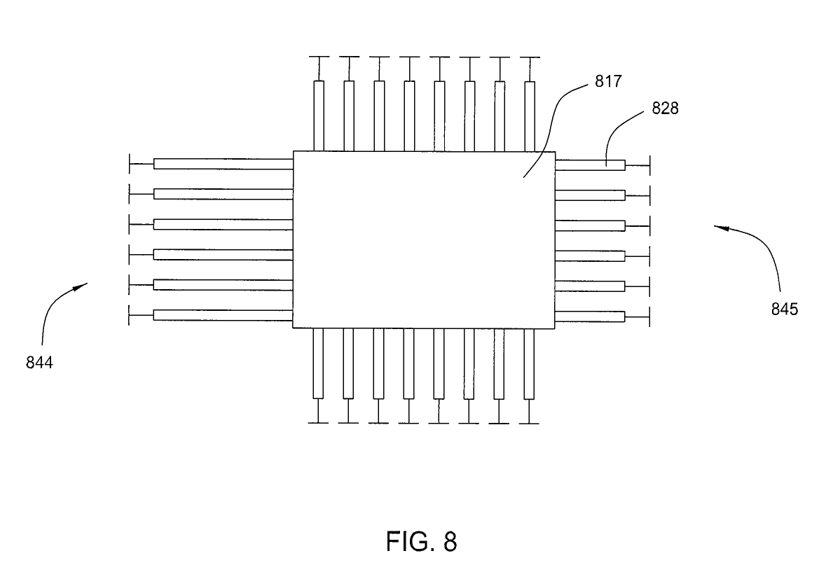

As shown in FIG. 7, RF returning straps along one side of a substrate support 717 may be arranged by varying length and varying capacitor. A plurality of RF returning straps 728 are evenly distributed along a side of the substrate support 717. Spacing 741 between neighboring RF returning straps is substantially the same, width of each RF returning straps 728 is substantially the same, and length of each RF returning strap 728 varies along the side. In one embodiment, the length of RF returning straps 728 is longer near the ends of the side and gradually decreases towards the center of the side. However, one or more RF returning straps 743 with variable capacitor 742 are disposed near the center of the side. The variable capacitor 742 allows the RF returning strap 743 to be equivalent to a RF returning strap of shorter length. This arrangement is particularly useful when decreasing length of a RF returning strap will limit a range of motion of the substrate support 717. Although only one side of the substrate support 717 is shown, remaining sides of the substrate support 717 are also connected to a plurality of RF returning straps. Similar RF returning strap arrangement or different RF returning strap arrangement can be applied to the remaining sides not shown.

FIG. 8 schematically illustrates a RF returning strap arrangement to compensate chamber asymmetry in accordance with one embodiment of the present invention. As shown in FIG. 8, a plurality of RF returning straps 828 are distributed along four sides of a rectangle substrate support body 817, similar to the support body 217 of FIG. 2A. The arrangement of the RF returning straps 828 is asymmetrical. Particularly, the RF returning straps coupled to side 844 are different from the RF returning straps coupled to side 845 opposing the side 844. This arrangement may be useful to correct chamber asymmetric chamber geometry caused by a slit valve positioned near the side 845.

While the foregoing is directed to embodiments of the present invention, other and further embodiments of the invention may be devised without departing from the basic scope thereof, and the scope thereof is determined by the claims that follow.

What is claimed is:

1. A method for processing a substrate using plasma, comprising:
providing a process chamber defining a processing volume, wherein a substrate support is disposed in the processing volume, a gas distribution plate connected with a radio frequency (RF) power source is disposed over the substrate support, and a periphery of the substrate support is connected with the radio frequency power source via a plurality of RF returning straps;
flowing one or more processing gases to the processing volume through the distribution plate; and
applying a radio frequency power to the gas distribution plate to generate a plasma from the one or more processing gases in the processing volume,
wherein impedance of one or more RF returning straps has been modified to adjust local plasma distribution between the gas distribution plate and the substrate.

2. The method of claim 1, wherein the impedance of the RF returning straps has been modified to increase local plasma distribution.

3. The method of claim 1, wherein impedance of the one or more RF returning straps has been modified by adjusting location of the RF returning straps, adjusting length of the RF returning straps, adjusting spacing between the RF returning straps, adjusting width of the RF returning straps, adding variable capacitors to the RF returning straps, or combination thereof.

4. The method of claim 3, wherein impedance is modified by moving the RF returning straps away from any corners of the substrate support.

5. The method of claim 3, wherein impedance is modified by lengthening the RF returning straps disposed near corners of the substrate support.

6. The method of claim 3, wherein adjusting impedance comprises widening the RF returning straps disposed away from corners of the substrate support.

7. The method of claim 3, wherein impedance is modified by increasing spacing between the RF returning straps disposed near corners of the substrate support.

8. The method of claim 2, wherein impedance of the one or more RF returning straps is modified by adjusting location of the plurality of RF returning straps.

9. An apparatus for processing a substrate, comprising:
a chamber body defining a processing volume, wherein the chamber body has a slit valve opening configured to allow passages of substrates;
a substrate support disposed in the processing volume, wherein the substrate support is configured to receive a substrate on a supporting surface and to support the substrate during processing;
a gas distribution plate disposed in the processing volume and above the substrate support, wherein the gas distribution plate is configured to deliver one or more processing gas;
a radio frequency power source connected with the gas distribution plate; and
a plurality of RF returning straps connected between a periphery of the substrate support and the radio frequency power source, wherein the plurality of RF returning straps is disposed such that impedance between the substrate support and the radio frequency power source varies along the periphery of the substrate support.

10. The apparatus of claim 9, wherein the substrate support is polygonal, and no RF returning strap is connected to corners of the substrate support.

11. The apparatus of claim 10, wherein the impedance between the substrate support and the radio frequency power source is varied by changing length of the RF returning straps, changing width of the RF returning straps, changing spacing of the RF returning straps, adding variable capacitors to the RF returning straps, or combinations thereof.

12. The apparatus of claim 11, wherein length of RF returning straps along a side of the substrate support varies.

13. The apparatus of claim 11, wherein width of RF returning straps along a side of the substrate support varies.

14. The apparatus of claim 11, wherein spacing between RF returning straps along a side of the substrate support varies.

15. The apparatus of claim 10, wherein at least one of the plurality of RF returning straps comprises a capacitor.

16. An apparatus for processing a substrate, comprising:
a chamber body defining a processing volume;
a first electrode disposed in the processing volume;
a second electrode disposed in the processing volume, wherein the second electrode is opposing the first electrode and the first and second electrodes form a plasma volume therebetween;
a radio frequency power source coupled to the first electrode; and
a plurality of RF returning straps coupled between the second electrode and a body at a predetermined electrical potential, wherein the plurality of RF returning straps are coupled to a periphery of the second electrode, and impedance of the plurality of RF returning straps varies along the periphery of the second electrode.

17. The apparatus of claim 16, wherein the plurality of RF returning straps vary in length, width, spacing, or combinations thereof.

18. The apparatus of claim 17, wherein at least one of the plurality of RF returning straps comprises a capacitor.

19. The apparatus of claim 17, wherein the plurality of RF returning straps are disposed away from any corners of the second electrode.

20. The apparatus of claim 19, wherein the RF returning straps disposed near the slit valve opening have smaller impedance than the RF returning straps away from the slit valve opening.
